(19) United States
(12) Patent Application Publication
(10) Pub. No.: US 2017/0194235 A1
(43) Pub. Date: Jul. 6, 2017

(54) LEAD FRAME AND SEMICONDUCTOR PACKAGE STRUCTURE

(71) Applicant: Chang Wah Technology Co., Ltd., Kaohsiung City (TW)

(72) Inventor: Chia-Neng Huang, Kaohsiung City (TW)

(21) Appl. No.: 15/162,916

(22) Filed: May 24, 2016

(30) Foreign Application Priority Data
Jan. 6, 2016 (TW) 105200111

(51) Int. Cl. H01L 23/495; H01L 21/48

(52) U.S. Cl. CPC H01L 23/49541; H01L 23/49558; H01L 21/4828; H01L 23/4952

(57) ABSTRACT

A lead frame includes an outer frame portion, a die pad surrounded by the outer frame portion, a plurality or spaced apart lead units extending from outer frame portion toward the die pad, and an encapsulant. Each of the lead units includes a contact portion extending from the outer frame portion, a leg portion laterally extending from the contact portion toward the die pad, and a support portion downwardly extending from the leg portion and being spaced apart from the die pad by a gap. The contact portion, the leg portion and the support portion cooperatively define a recess thereamong. The encapsulant fills the recess and the gap. A semiconductor package structure containing the lead frame is also disclosed.

### CROSS-REFERENCE TO RELATED APPLICATION

This application claims priority of Taiwanese Patent Application No. 105200111, filed on Jan. 6, 2016.

### FIELD

The disclosure relates to a lead frame and a semiconductor package structure, and more particularly to a lead frame with a support portion and a semiconductor package structure containing the lead frame.

### BACKGROUND

A quad flat no-lead (QFN) package typically has a smaller size comparing with a leaded chip carrier package that includes a plurality of pins extending outwardly. In addition, the QFN package has a relatively short signal transmission path, thus it can be applied to high frequency and high speed electronic devices.

Referring to FIG. 1, a conventional semiconductor package structure with a QFN package includes a lead frame 11, a chip 12, a plurality of wires 13, and an encapsulant 14. The lead frame 11 includes an outer frame portion 114, a die pad 112 which is surrounded by the outer frame portion 114 and on which the chip 12 is disposed, and a plurality of spaced-apart lead units 110 which extend from the outer frame portion 114 toward the die pad 12. Each of the lead units 110 includes a contact portion 111 extending from the outer frame portion 114, and a leg portion 113 extending from the contact portion 111 toward the die pad 112. The lead units 110, the die pad 112, and the outer frame portion 114 cooperatively define a space 115 thereamong. The wires 13 connect the die pad 112 and the lead units 110. The encapsulant 14 covers the chip 12 and a top surface of the lead frame 11, and fills the space 115. The QFN package is fabricated by removing the outer frame portion 114 from the semiconductor package structure using saw cutting techniques or etching techniques.

However, a distance between the chip 12 and the leg portion 113 of each of the lead units 110 is increased if the chip 12 was miniaturized. The wires 13 have to be lengthened accordingly, which may decrease the efficiency of electrical signal transmission. Instead of lengthening the wires 13, the leg portion 113 of each of the lead units 110 may further extend toward the die pad 112. However, since an end of the leg portion 113 of each of the lead units 110 which is away from the outer frame portion 114 is suspended, the leg portion 113 of each of the lead units 110 is likely to be deformed due to a lack of support, and may even collapse when filling the space 115 with the encapsulant 14.

### SUMMARY

Therefore, an object of the disclosure is to provide a lead frame that can alleviate at least one of the drawbacks of the prior art.

The lead frame includes an outer frame portion, a die pad, a plurality of spaced apart lead units, and an encapsulant.

The die pad is surrounded by the outer frame portion and has a mounting surface for mounting a chip thereon.

The lead units extend from the outer frame portion toward the die pad. Each of the lead units includes a contact portion extending from the outer frame portion and being used for electrically contacting an external device, a leg portion laterally extending from the contact portion toward the die pad, and a support portion downwardly extending from the leg portion and being spaced apart from the die pad by a gap. The contact portion, the leg portion, and the support portion of each of the lead units cooperatively define a recess thereamong. The contact portion and the support portion of each of the lead units are spaced apart from each other by the recess. The encapsulant fills the recess of each of the lead units and the gap between the die pad and each of the lead units.

According to the disclosure, the semiconductor packaging structure includes the aforesaid lead frame, a chip, and a plurality of wires.

The chip is disposed on the mounting surface of the die pad of the lead frame.

The wires electrically connect the chip and the lead units of the lead frame.

### BRIEF DESCRIPTION OF THE DRAWINGS

Other features and advantages of the disclosure will become apparent in the following detailed description of the embodiments with reference to the accompanying drawings, of which:

FIG. 1 is a cross sectional view illustrating a conventional semiconductor package structure with a QFN package;

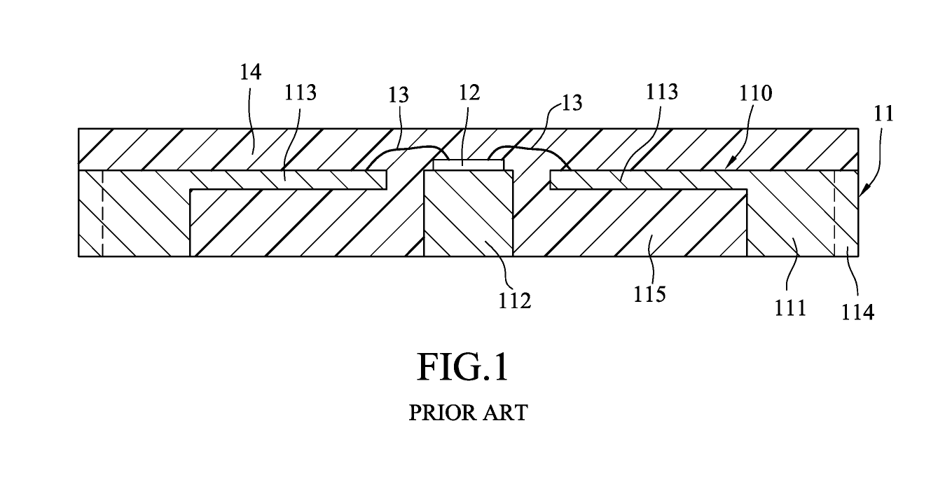

FIG. 2 is a cross sectional view illustrating an embodiment of a lead frame according to the disclosure;

FIG. 3 illustrates a method of making the embodiment of FIG. 2; and

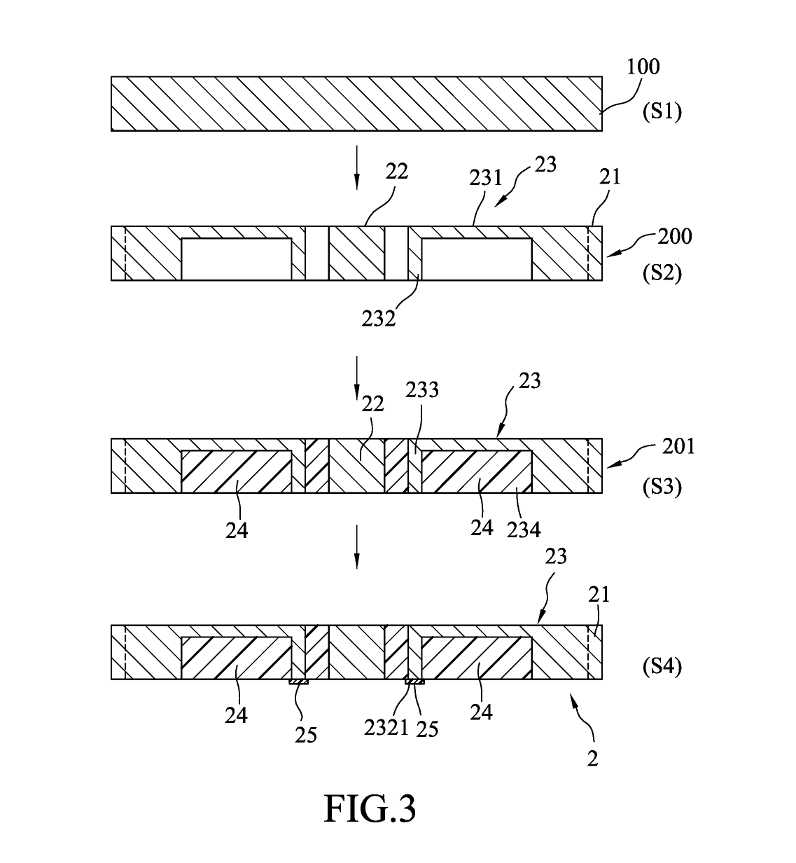

FIG. 4 is a cross sectional view illustrating an embodiment of a semiconductor package structure according to the disclosure.

### DETAILED DESCRIPTION

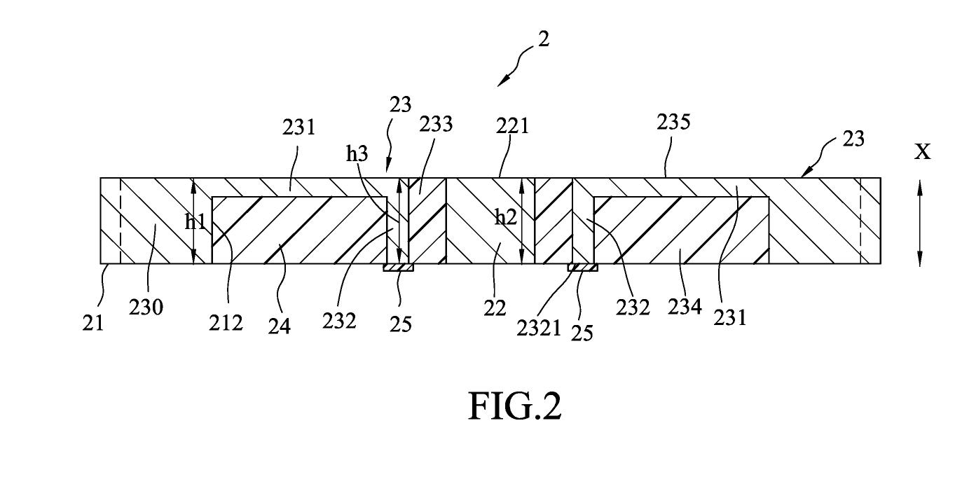

Referring to FIG. 2, an embodiment of a lead frame 2 according to the disclosure includes an outer frame portion 21, a die pad 22, a plurality of spaced apart lead units 23, an encapsulant 24, and a plurality of insulating layers 25.

The die pad 22 is surrounded by the outer frame portion 21 and has a mounting surface 221 for mounting a chip thereon.

The lead units 23 extend from the outer frame portion 21 toward the die pad 22. Each of the lead units 23 includes a contact portion 230 extending from the outer frame portion 21 and being used for electrically contacting an external device (not shown), a leg portion 231 laterally extending from an upper portion of the contact portion 230 toward the die pad 22, and a support portion 232 downwardly extending from the leg portion 231 and being spaced apart from the die pad 22 by a gap 233. The contact portion 230, the leg portion 231, and the support portion 232 of each of the lead units 23 cooperatively define a recess 234 thereamong. The support portion 232 and the contact portion 230 of each of the lead units 23 are spaced apart from each other by the recess 234. In one embodiment, the contact portion 230, the leg portion 231 and the support portion 232 of each of the lead units 23 are integrally formed as one piece. In one embodiment, the outer frame portion 21, the lead units 23, and the die pad 22 are made from the same material. In one embodiment, each of the lead units 23 has a top surface 235 that extends across the contact portion 230, the leg portion 231 and the support portion 232, and that is flush with the mounting surface 221 of the die pad 22.

The support portion 232 of each of the lead units 23 has a lower surface 2321 that is opposite to the top surface 235 of each of the lead units 23 in an up-down direction (X). The contact portion 230 also has a lower surface that is opposite to the top surface 235 of each of the lead units 23 in the up-down direction (X). The die pad 22 has a base surface that is opposite to the mounting surface 221 in the up-down direction (X).

The encapsulant 24 fills the recess 234 of each of the lead units 23 and the gap 233 between the die pad 22 and each of the lead units 23. The encapsulant 24 does not cover the top surface 235, the lower surface 2321 of the support portion 232, and the lower surface of the contact portion 230 of each of the lead units 23. The encapsulant 24 also does not cover the mounting surface 221 and the base surface of the die pad 22.

Each of the insulating layers 25 covers the lower surface 2321 of the support portion 23 of a respective one of the lead units 23. The insulating layers 25 may be made from a solder resist material.

In certain embodiment, the die pad 22 has a height (h₂) in the up-down direction (X). For each of the lead units 23, the contact portion 230 has a height (h₁) in the up-down direction (X), and the support portion 232 has a height (h₃) in the up-down direction (X). The height (h₁), the height (h₂), and the height (h₃) are substantially the same.

A method of making the embodiment of the lead frame 2 according to the disclosure includes steps S1, S2, S3 and S4. In step S1, a conductive substrate 100 which is made from, e.g., a copper-based alloy or an iron-nickel-based alloy, is provided. In step S2, the conductive substrate 100 is patterned using etching techniques to form a preformed lead frame 200 which includes the outer frame portion 21, the die pad 22 and the lead units 23 each containing the contacting portion 230, the leg portion 231 and the support portion 232.

In step S3, the preformed lead frame 200 is disposed in a mold (not shown), and then an encapsulating material is filled in the recess 234 of each of the lead units 23 and the gap 233 between the die pad 22 and each of the lead units 23, followed by cooling the encapsulating material 240 so as to form the encapsulant 24. A partly finished lead frame 201 is thus obtained. The encapsulating material is an insulating material such as an epoxy resin.

In step S4, the partly finished lead frame 201 is removed from the mold, and then an insulating material, e.g., a solder resist material, is applied on the lower surface 2321 of the support portion 232 of each of the lead units 22 to form the insulating layer 25.

It should be noted that, for the fabrication of a plurality of lead frames 2 in a single manufacturing process, the conductive substrate 100 may be patterned to form a plurality of preformed lead frames 200.

In this embodiment, since the outer frame portion 21, the die pad 22 and the lead units 23 are patterned from the conductive substrate 100, they are made from the same material. In addition, since the height (h₂) of the die pad 22 is identical to the height (h₃) of the support portion 231 of each of the lead units 23, the support portion 232 could provide support for the leg portion 231. Therefore, deformation or collapse of the leg portion 231 of each of the lead units 23 during the manufacturing process can be prevented.

Furthermore, the encapsulant 24 fills the recess 234 of each of the lead units 23, thereby providing further support for the leg portion 231. The support provided by the support portion 232 and the encapsulant 24 filling in the recess 234 would make the lead frame 2 more stable and facilitate the operations of the subsequent chip mounting and wire bonding procedures.

The embodiment of the lead frame 2 according to the disclosure can be used in a quad flat no-lead (QFN) package.

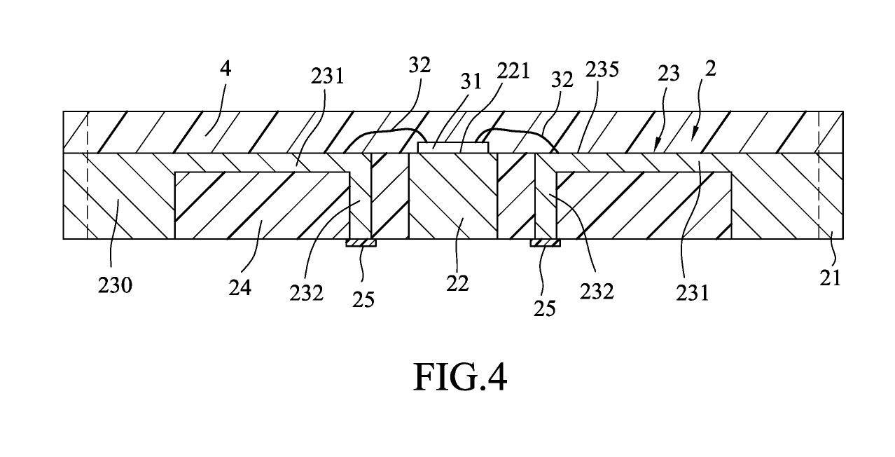

Referring to FIG. 4, an embodiment of a semiconductor package structure according to the disclosure includes the aforesaid lead frame 2, a chip 31, a plurality of wires 32, and an encapsulating layer 4. The chip 31 is disposed on the mounting surface 221 of the die pad 22 of the lead frame 2. The wires 32 electrically connect the chip 31 and the lead units 23 of the lead frame 2. The encapsulating layer 4 covers the chip 31, the wires 32 and the top surface 235 of each of the lead units 23.

In detail, the semiconductor package structure is fabricated by: disposing the chip 31 on the mounting surface 221 of the die pad 22 of the lead frame 2, placing the wires 32 that connect the chip 31 and the lead units 23 of the lead frame 2 using wire bonding techniques, and forming the encapsulating layer 4 on the chip unit 3, the wires 32, and the top surface 235 of each of the lead units 23 for coverage.

It should be noted that when the conductive substrate 100 is patterned to form a plurality of preformed lead frames 200, a plurality of chips 31 can be simultaneously mounted on the die pads 22 of the lead frames 2, followed by the wire bonding.

A QFN package may be fabricated by removing the outer frame portion 21 and the encalsulating layer 4 thereon from the semiconductor package structure using saw cutting techniques or etching techniques.

To sum up, with the support portion 232 and the encapsulant 24 filling in the recess 234, the leg portion 231 of each of the lead units 23 is stably supported, so that the drawbacks, such as collapse and deformation of the leg portions 231, may be alleviated. The production yield of the semiconductor package structure may be thus improved.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding various inventive aspects.

While the disclosure has been described in connection with what is considered the exemplary embodiments, it is understood that this disclosure is not limited to the disclosed embodiment but is intended to cover various arrangements included within the spirit and scope of the broadest interpretation so as to encompass all such modifications and equivalent arrangements.

1. A lead frame comprising:
an outer frame portion;
a die pad surrounded by said outer frame portion and having a mounting surface for mounting a chip thereon;
a plurality of spaced apart lead units extending from said outer frame portion toward said die pad, each of which includes a contact portion extending from said outer frame portion and being used for electrically contacting an external device, a leg portion laterally extending from said contact portion toward said die pad, and a support portion downwardly extending from said leg portion and being spaced apart from said die pad by a gap, said contact portion, said leg portion and said support portion cooperatively defining a recess thereamong, said support portion and said contact portion of each of said lead units being spaced apart from each other by said recess; and
an encapsulant filling said recess of each of said lead units and said gap between said die pad and each of said lead units.

2. The lead frame of claim 1, wherein each of said lead units has a top surface that extends across said contact portion, said leg portion and said support portion, and that is flush with said mounting surface of said die pad.

3. The lead frame of claim 1, wherein said contact portion, said leg portion and said support portion of each of the lead units are integrally formed as one piece.

4. The lead frame of claim 1, wherein each of said lead units has a top surface that extends across said contact portion, said support portion of each of said lead units having a lower surface that is opposite to said top surface of each of said lead units in an up-down direction (X), said lead frame further comprising a plurality of insulating layers each of which covers said lower surface of said support portion of a respective one of said lead units.

5. The lead frame of claim 4, wherein said insulating layers are made from a solder resist material.

6. The lead frame of claim 1, wherein said die pad has a height (h2) in the up-down direction (X), and, in each of said lead units, said contact portion has a height (h1) in the up-down direction (X) and said support portion has a height (h3) in the up-down direction (X), said height (h1), said height (h2), and said height (h3) being substantially the same.

7. The lead frame of claim 1, wherein said outer frame portion, said lead units and said die pad are made from the same material.

8. The lead frame of claim 1, wherein said encapsulant is made from an epoxy resin.

9. A semiconductor package structure comprising:
a lead frame of claim 1;
a chip which is disposed on said mounting surface of said die pad of said lead frame; and
a plurality of wires electrically connecting said chip and said lead units of said lead frame.

10. The semiconductor package structure of claim 9 further comprises an encapsulating layer which covers said chip, said wires and said top surface of each of said lead units.
